(19) United States
(12) Patent Application Publication
(10) Pub. No.: US 2024/0332409 A1
(43) Pub. Date: Oct. 3, 2024

(54) MULTI-CHANNEL HIGH ELECTRON MOBILITY TRANSISTOR WITH DOPED GATE FINS

(71) Applicant: Infineon Technologies Austria AG, Villach (AT)

(72) Inventors: Clemens Ostermaier, Villach (AT); Lauri Olavi Knuuttila, Villach (AT); Korbinian Reiser, Ottobrunn (DE)

(21) Appl. No.: 18/126,729

(22) Filed: Mar. 27, 2023

(51) Int. Cl. H01L 29/778; H01L 29/20; H01L 29/40; H01L 29/423; H01L 29/47; H01L 29/66

(52) U.S. Cl. CPC H01L 29/7786; H01L 29/2003; H01L 29/401; H01L 29/42316; H01L 29/475; H01L 29/66462

(57) ABSTRACT

A high-electron mobility transistor includes a semiconductor body includes a plurality of type III-nitride semiconductor layers stacked on top of one another, thereby forming a plurality of two-dimensional first charge type gas channels; source and drain electrodes that are laterally spaced apart from one another and in ohmic contact with each of the two-dimensional first charge type gas channels; a gate structure including a plurality of gate columns that extend into the semiconductor body and define gate fin portions of the semiconductor body, wherein the gate structure is configured to control a conductive connection between the source and drain electrodes by controlling a conductive state of each of the two-dimensional first charge type gas channels within the gate fin portions, and wherein the gate fin portions are doped with second conductivity type dopant atoms, thereby locally reducing a concentration of free first charge type carriers within the gate fin portions.

### BACKGROUND

HEMTs (high-electron-mobility Field Effect Transistors) also known as heterostructure FETs (HFETs) and modulation-doped FET (MODFETs) offer high conduction and low losses in comparison to many conventional semiconductor transistor designs. These advantageous conduction characteristics make HEMTs desirable in applications including, but not limited to, use as switches in power supplies and power converters, electric cars, air-conditioners, and in consumer electronics, for example. Designers are constantly seeking ways to improve the performance of HEMTs, e.g., power consumption and voltage blocking capability. Exemplary device parameters that designers seek to improve include leakage current, threshold voltage (VTH), drain-source on-state resistance (RDSON), and maximum voltage switching capability, to name a few. Multi-channel HEMTs that utilize more than one device channel are currently under investigation. This device concept advantageously lowers the RDSON of the device by providing multiple two-dimensional charge carrier gas channels in parallel between the source and drain. One challenge in fabricating multi-channel HEMTs is that very narrow gate fins are needed to enable full depletion of the two-dimensional charge carrier gas channels and facilitate device turn off. These very narrow gate fins may be difficult or impossible to achieve in current semiconductor processing technology.

### SUMMARY

A high-electron mobility transistor is disclosed. According to an embodiment, the high-electron mobility transistor comprises a semiconductor body comprising a plurality of type III-nitride semiconductor layers stacked on top of one another, thereby forming a plurality of two-dimensional first charge type gas channels that are vertically spaced apart from one another; source and drain electrodes that are laterally spaced apart from one another and in ohmic contact with each of the two-dimensional first charge type gas channels; a gate structure comprising a plurality of gate columns that extend into the semiconductor body and define gate fin portions of the semiconductor body in between two of the gate columns, wherein the gate structure is configured to control a conductive connection between the source and drain electrodes by controlling a conductive state of each of the two-dimensional first charge type gas channels within the gate fin portions, and wherein the gate fin portions are doped with second conductivity type dopant atoms, thereby locally reducing a concentration of free first charge type carriers within the gate fin portions.

According to another embodiment, the high-electron mobility transistor comprises a semiconductor body comprising a plurality of type III-nitride semiconductor layers stacked on top of one another, thereby forming a plurality of two-dimensional first charge type gas channels that are vertically spaced apart from one another; source and drain electrodes that are laterally spaced apart from one another and in ohmic contact with each of the two-dimensional first charge type gas channels; a gate structure comprising a plurality of gate columns that extend into the semiconductor body and define gate fin portions of the semiconductor body in between two of the gate columns, wherein the gate structure is configured to control a conductive connection between the source and drain electrodes by controlling a conductive state of each of the two-dimensional first charge type gas channels within the gate fin portions, wherein the high-electron mobility transistor is a normally-off device, and wherein a width of the gate fin portions is at least 80 nm.

A method of forming a high-electron mobility transistor is disclosed. According to an embodiment, the method comprises providing a semiconductor body comprising a plurality of type III-nitride semiconductor layers stacked on top of one another, thereby forming a plurality of two-dimensional first charge type gas channels that are vertically spaced apart from one another; forming source and drain electrodes that are laterally spaced apart from one another and in ohmic contact with each of the two-dimensional first charge type gas channels; forming a gate structure comprising a plurality of gate columns that extend into the semiconductor body and define gate fin portions of the semiconductor body in between two of the gate columns, the gate structure being configured to control a conductive connection between the source and drain electrodes by controlling a conductive state of the plurality of two-dimensional first charge type gas channels within the gate fin portions, and doping the gate fin portions with second conductivity type dopant atoms, thereby locally reducing a concentration of free first charge type carriers within the gate fin portions.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A and 1B, illustrates a high-electron-mobility field effect transistor, according to an embodiment. FIG. 1A illustrates a cross-sectional view of the high-electron-mobility field effect transistor; and FIG. 1B illustrates a plan-view of the high-electron-mobility field effect transistor.

FIG. 2 illustrates a close-up view of a gate fin portion of the high-electron-mobility field effect transistor along the cross-sectional line I-I′ shown in FIG. 1, according to an embodiment.

FIG. 3 illustrates a close-up view of a gate fin portion of the high-electron-mobility field effect transistor along the cross-sectional line I-I′ shown in FIG. 1, according to another embodiment.

FIG. 4 illustrates a close-up view of a gate fin portion of the high-electron-mobility field effect transistor along the cross-sectional line I-I′ shown in FIG. 1, according to another embodiment.

### DETAILED DESCRIPTION

Embodiments of a high-electron-mobility field effect transistor with a multi-channel configuration are disclosed herein. The high-electron-mobility field effect transistor is formed in a semiconductor body that comprises a plurality of two-dimensional first charge type gas channels, each of which form an active device channel between the source and drain electrodes of the transistor. The gate structure of the transistor is formed by a plurality of gate columns that extend into the semiconductor body, thereby defining gate fin portions in between two of the gate columns. The gate structure controls the on/off state by locally depleting and repopulating the two-dimensional first charge type gas channels that run through the gate fin portions. The gate fin portions are doped with second conductivity type dopants. This reduces the concentration of free first charge type carriers within the gate fin portions, which in turn facilitates a favorable shift in the relationship between the width of the gate fin portions and the threshold voltage of the device. That is, the same threshold voltage can be obtained with a wider gate fin portion. This concept can be used to fabricate a normally-off multi-channel high-electron-mobility field effect transistor with wider gate fin portions that are more easily fabricated.

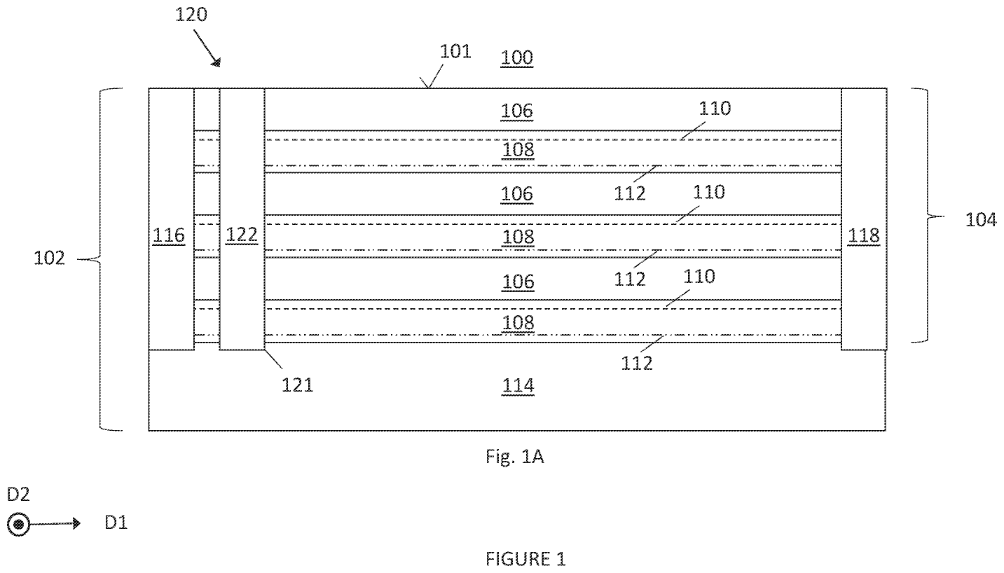

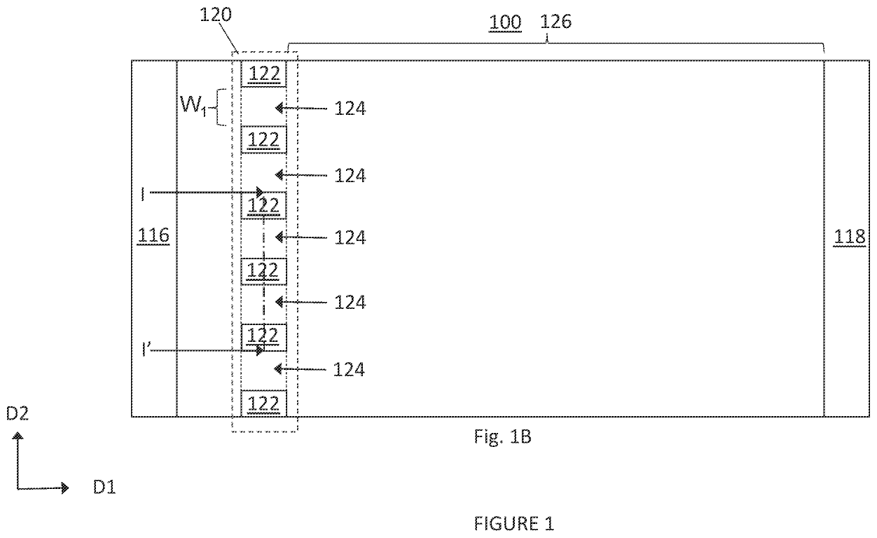

Referring to FIG. 1, a high-electron mobility transistor 100 is formed in a semiconductor body 102. The semiconductor body 102 comprises a channel region 104 that comprises a plurality of type III-nitride semiconductor layers stacked on top of one another. These type III-nitride semiconductor layers are arranged in layer pairs, wherein each layer pair comprises a barrier layer 106 and a channel layer 108. The barrier layer 106 is formed from a material with a different bandgap as the channel layer 108. The bandgap difference may result from a difference in metal alloy concentration of the III-nitride semiconductor material between adjoining layers. For example, the barrier layer 106 may be a layer of AlₓGa1₋ₓN and the channel layer 108 may be a layer of Al_{y}Ga1_{-y}N, wherein x>y. As a result of the bandgap difference between the barrier layer 106 and the channel layer 108 from each layer pair, a two-dimensional charge carrier gas channel arises near each heterojunction interface. Due to the polarization fields, two-dimensional charge carrier gases form with opposite polarities in an alternating manner along a vertical direction of the semiconductor body. In particular, the channel region 104 comprises a plurality of two-dimensional first charge type gas channels 110 and a plurality of two-dimensional second charge type gas channels 112, with the second charge carrier type being opposite from the first conductivity type. For example, the two-dimensional first charge type gas channels 110 may correspond to 2DEG (two-dimensional electron gas) channels and the two-dimensional second charge type gas channels 112 may correspond to 2DHG (two-dimensional hole gas) channels. In general, this concept can be used to create a device with any number of the two-dimensional first charge type gas channels 110, with the two-dimensional second charge type gas channels 112 alternating in between. The uppermost and/or lowermost two-dimensional charge carrier gas may vary, depending on the adjoining layers. For instance, measures may be taken to suppress one of the two-dimensional second charge type gas channels 112 from above or below the channel region 104.

Additional layers or regions may be provided at the upper side 101 of the channel region 104 that are not shown in FIG. 1A for the sake of simplicity. These additional layers and/or structures may comprise further semiconductor layers, e.g., capping layers, electrically insulating layers and/or protective layers, e.g., passivation layers, interlayer dielectrics, etc., metallization layers, e.g., metal contact pads, bond pads, etc.

The semiconductor body 102 further comprises a substrate region 114 below the channel region 104. The substrate region 114 corresponds to a portion of the semiconductor body 102 that does not contain an active device channel. The substrate region 114 may comprise multiple regions or layers of material that are not specifically identified in the figure. For example, the substrate region 114 may comprise a base substrate that is used as a seed region to epitaxially grow type III-nitride semiconductor material thereon. This base substrate may comprise a variety of semiconductor materials such as silicon (Si), sapphire, silicon carbide (SiC) or silicon germanium (SiGe), etc. According to an embodiment, the base substrate is a commercially available semiconductor wafer, such as a bulk silicon wafer or a SOI (silicon on insulator) wafer. The substrate region 114 may additionally comprise a lattice transition region that is configured to alleviate mechanical stress attributable to crystalline lattice mismatch between the base substrate and the semiconductor material of the channel region 104, e.g., a lattice mismatch between silicon and GaN/AlGaN. Separately or in combination, the substrate region 114 may comprise a back-barrier region immediately underneath the lowermost channel layer 108 of the channel region 104 that is used to increase carrier confinement and prevent leakage through the substrate region 114.

The high-electron mobility transistor 100 comprises source and drain electrodes 116, 118 that are laterally spaced apart from one another in a current flow direction D1 of the device. The source and drain electrodes 116, 118 are in ohmic contact with each of the two-dimensional first charge type gas channels 110. The source and drain electrodes 116, 118 may be formed by trenches that extend from the upper side 101 of the channel region 104 to reach the lowermost two-dimensional first charge type gas channel 110. These trenches may be filled with a semiconductor material of the first conductivity type, thereby forming an ohmic connection with the two-dimensional first charge type gas channels 110. For example, in the case that the two-dimensional first charge type gas channels 110 are 2DEG channels, the source and drain electrodes 116, 118 may comprise n-type type III-nitride semiconductor material, e.g., n-type GaN/AlGaN. In this device arrangement, the two-dimensional second charge type gas channels 112 are parasitic 2DHG channels that are not used as active device channels.

The high-electron mobility transistor 100 comprises a gate structure 120 that is arranged laterally between the source and drain electrodes 116, 118 in the current flow direction D1 of the device. The gate structure comprises a plurality of gate columns 122 that are laterally spaced apart from one another in a second lateral direction D2 that is perpendicular to the current flow direction D1. The gate columns 122 extend into the semiconductor body 102 to reach the lowermost two-dimensional first charge type gas channel 110. The gate columns 122 define gate fin portions 124 of the semiconductor body 102. That is, portions of the semiconductor body 102 that occupy the space in the second lateral direction D2 between two immediately adjacent ones of the gate columns 122 correspond to the gate fin portions 124. The geometry of the gate fin portions 124 may vary from what is shown. For example, the gate columns 122 may be tapered in the second lateral direction D2 such that the width of the gate fin portions 124 decreases moving towards the drain electrode 118. Separately or in combination, Separately or in combination, the gate columns 122 may be tapered in a vertical direction that is perpendicular to the upper surface 101 such that the width of the gate fin portions 124 decreases moving towards the substrate region 114.

The working principle of the high-electron mobility transistor 100 is as follows. The high-electron mobility transistor 100 is configured to control a load current flowing between the source and drain electrodes 116, 118 via the two-dimensional first charge type gas channels 110. This load current flows through the gate fin portions 124 in between the gate columns 122. The gate structure 120 provides on-off control by locally depleting and repopulating the two-dimensional first charge type gas channels 110 within the gate fin portions 124 based on the gate-source potential. According to an embodiment, the gate structure 120 comprises second conductivity type semiconductor material that is used to locally deplete the two-dimensional first charge type gas channels 110 in the vicinity of the gate columns 122. For example, the two-dimensional first charge type gas channels 110 may be 2DEG channels, and the gate structure 120 may comprise p-type semiconductor material, e.g., p-type GaN or p-type AlGaN that depletes the 2DEG channels. The threshold voltage of the high-electron mobility transistor 100 can be determined by the physical parameters of the gate structure 120. For example, the dopant concentration of the gate columns 122, size of the gate columns 122, and width of the gate fin portions 124 in the second lateral direction D2, can be tailored to achieve a desired threshold voltage. The high-electron mobility transistor 100 may be a so-called normally off device. According to this configuration, the physical parameters of the gate columns 122 are selected such that the two-dimensional first charge type gas channels 110 within the gate fin portions 124 are completely depleted and hence non-conductive at zero gate-source bias.

According to an embodiment, the gate columns 122 comprise second conductivity type semiconductor material that directly interfaces with the type III-nitride semiconductor layers of the gate fin portions 124. For example, the gate columns 122 can be formed gate trenches 121 that extend from the upper side 101 of the channel region 104 and are filled with second conductivity type semiconductor material, thus forming a direct interface of the second conductivity type semiconductor material at the sidewalls of the gate trenches 121. This arrangement may form a so-called p-n junction gate configuration, whereby a p-n junction exists between the gate structure 120 and each of the active device channels. For example, the gate columns 122 may comprise p-type GaN or p-type AlGaN that forms a p-n junction 2DEG channels corresponding to the two-dimensional first charge type gas channels 110. In this case, the ‘n’ region of the p-n junction corresponds to the 2DEG which forms the active device channel. According to another embodiment, the gate structure 120 is configured as a so-called p-i-n diode whereby the gate structure comprises a layer of undoped or low doped material, e.g., AlGaN, in between the second conductivity type semiconductor material and the two-dimensional first charge type gas channels 110. According to another embodiment, gate structure 120 is configured as so-called MIS (metal insulator semiconductor) gate whereby the gate structure 120 comprises a metal gate electrode and a layer of electrically insulating material, e.g., SiO₂, SiN, etc., that separates the metal gate electrode from the two-dimensional first charge type gas channels 110. A variation of this structure replaces the metal gate electrode with a highly conductive semiconductor material, such as highly doped polysilicon. According to another embodiment, the gate structure 120 has a Schottky gate configuration, whereby the gate structure 120 comprises a metal Schottky contact material that directly interfaces with the type-III nitride material of the channel region 104 and forms a Schottky junction.

The multi-channel configuration of the high-electron mobility transistor 100, while advantageous in many respects, presents certain challenged with respect to the formation of the gate structure 120. In particular, the gate structure 120 must be able to deplete the two-dimensional first charge type gas channels 110 within the within the gate fin portions 124 by a lateral electric field that emanates out from the gate columns 122 in a lateral direction that is perpendicular to the upper side 101 of the semiconductor body 102. Device turn-off only occurs when the electric field is sufficient to deplete two-dimensional first charge type gas channels 110 across a complete width W₁ of the gate fin portions 124. In the case of a normally-off device configuration, the electric field emitted by the gate columns 122 at zero gate-source bias must be sufficient to deplete two-dimensional first charge type gas channels 110 across the complete width W₁ of the gate fin portions 124. This places a significant constraint on the maximum width W₁ of the gate fin portions 124. The width W₁ of the gate fin portions 124 that is necessary to achieve a normally-off device configuration may be difficult or impossible to fabricate by current semiconductor processing methods. As is known, due to the practical limitations of modern lithography techniques, very narrow trenches become difficult to form and at a certain point impossible. For this reason, semiconductor processing technologies impose minimum feature sizes that correspond to the smallest manufacturable size that a feature such as a trench can be reliably formed. In current device technologies based on GaN/AlGAN heterojunctions and p-type GaN gate structures, the width W₁ of the gate fin portions 124 must be very thin. to achieve normally-off operation. For example, a normally-off device configuration may be obtained with gate fin widths of less than 50 nm, e.g., in the range of 20 nm-30 nm. These values may be close to or below the minimum feature size, and in any case may only be formed with significant variance that may detrimentally impact yield. Moreover, the minimum achievable width W₁ of the gate fin portions 124 may limit the thickness of the channel region 104, which in turn limits the number of active device channels that can be provided in a single device.

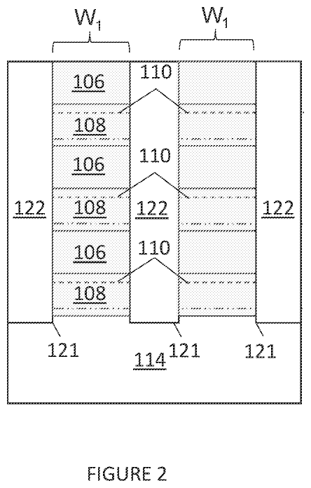

Referring to FIG. 2, an embodiment of the high-electron mobility transistor 100 is shown wherein the gate fin portions 124 are doped with second conductivity type dopant atoms. The second conductivity type dopant atoms locally reduce a concentration of free first charge type carriers within the gate fin portions 124. That is, the underlying type III-nitride semiconductor layers within the gate fin portions 124 are doped to have a net second conductivity type dopant concentration. For example, in the case that the barrier layer 106 is a layer of AlₓGa1₋ₓN and the channel layer 108 is a layer of Al_{y}Ga1_{-y}N, wherein x>y, the gate fin portions 124 are doped with p-type dopant atoms, e.g., magnesium (Mg), to form p-type GaN/AlGaN that locally reduces the concentration of free electrons within the gate fin portions 124. The second conductivity type doping of the gate fin portions 124 advantageously facilitates a favorable shift in the relationship between the width W₁ of the gate fin portions 124 and the threshold voltage of the high-electron mobility transistor 100.

The gate fin portions 124 may be doped with second conductivity type dopant atoms according to a technique whereby the gate columns 122 comprise second conductivity type semiconductor material that directly interfaces with the type III-nitride semiconductor layers of the gate fin portions 124, and the second conductivity type dopant atoms are diffused out from the second conductivity type semiconductor material of the gate columns 122. In this context, an arrangement whereby second conductivity type dopant atoms are diffused out from the second conductivity type semiconductor material of the gate columns 122 refers to a distribution of the second conductivity type dopant atoms that is radially centered by the second conductivity type semiconductor material within the gate trenches 121.

An embodiment for doping the gate fin portions 124 with second conductivity type dopant atoms comprises the following. After formation of each of the type III-nitride semiconductor layers from the channel region 104, the plurality of gate trenches 121 may be formed, e.g., according to a masked etching technique. Subsequently, an epitaxial deposition process may be performed to deposit second conductivity type semiconductor material within each of the gate trenches 121. Concurrently or thereafter, second conductivity type dopant atoms laterally diffuse outward from the deposited semiconductor material across the sidewalls of the gate trenches 121. The time and temperature of the gate material deposition process may be controlled to achieve a desired degree of out-diffusion. If desired, a separate annealing step may be performed after the gate material epitaxial deposition process to achieve further movement of the second conductivity type dopant atoms, if necessary.

The lateral out-diffusion of the second conductivity type dopant atoms as described above advantageously can be used to provide a substantially vertically homogeneous doping of the type III-nitride semiconductor layers. That is, the second conductivity type dopant atoms are homogeneous in a vertical direction of the semiconductor body 102 that is perpendicular to the upper side 101. As a result of the substantially vertically homogeneous doping of the type III-nitride semiconductor layers, the second conductivity type dopant atoms are not particularly confined to the two-dimensional first charge type gas channels 110, and thus the impact of the second conductivity type dopant atoms on the mobility of the first charge type carriers within two-dimensional first charge type gas channels 110 is minimized. The only location in which this may not hold true is in the vicinity of the uppermost two-dimensional first charge type gas channel 110. This is because the deposition of the second conductivity type semiconductor material within each of the gate trenches 121 may result in the formation of a complete layer of the second conductivity type semiconductor material on the upper side 101 of the channel region 104. Second conductivity type dopant atoms may diffuse downward from this complete layer and negatively impact the conductivity of the uppermost two-dimensional first charge type gas channel 110. This issue may be resolved at least by one of the following ways. According to one technique, an additional layer, e.g., a dielectric layer, may be formed on the upper side 101 of the channel region 104 prior to the depositing of the second conductivity type semiconductor material. This additional layer may inhibit the downward diffusion of second conductivity type dopant atoms into the uppermost layer of the channel region 104. This additional layer can be subsequently removed, e.g., by etching, or remain intact, e.g., as a passivation layer. According to another technique, the thickness of the uppermost layer of the channel region 104 is selected to ensure that the downward diffusion of second conductivity type dopant atoms does not significantly disrupt the uppermost two-dimensional first charge type gas channel 110.

Alternative techniques for doping the gate fin portions 124 with second conductivity type dopant atoms may include techniques whereby the doping is performed concurrently with the formation of each type III-nitride semiconductor layer within the channel region 104. For instance, after each epitaxial deposition step that forms one of the channel layer 106 or the barrier layer 108, an implantation process may be used to selectively dope the semiconductor material in the vicinity of the gate fin portions 124. An implantation mask may be formed above each type III-nitride semiconductor layer and have openings corresponding to the location of the gate fin portions 124.

In each of the above-described doping techniques, the process is carried out such that the second conductivity type dopant concentration is substantially confined to the gate fin portions 124. That is, the high-electron mobility transistor 100 is configured such that type III-nitride semiconductor layers within the gate fin portions 124 comprise a high concentration of the second conductivity type dopant while remaining parts of the III-nitride semiconductor layers of the channel region 108 outside of the gate fin portions 124 are substantially intrinsically doped. Thus, in the above-described technique wherein the gate columns 122 are used as a dopant source, the doping can be controlled such that a substantial majority of the second conductivity type dopant atoms, e.g., 95%, 99%, etc., diffuse no further than one half of the width W₁ of the gate fin portions 124, thereby minimizing out-diffusion of second conductivity type dopant atoms into an access region 126 of the device that is between the gate structure 120 and the drain electrode 118.

According to the embodiment of FIG. 2, the second conductivity type dopant atoms are substantially laterally homogeneously distributed across a width W₁ of each of the gate fin portions 124. In this context, a substantially laterally homogeneous distribution refers to an arrangement whereby the greatest difference in dopant concentration along the entire width W₁ of the gate fin portions 124 at one vertical level is no more than 10%. This substantially laterally homogeneous distribution can be achieved through appropriate selection of the diffusion parameters, e.g., time and temperature and/or the width W₁ of the gate fin portions 124. The second conductivity type dopant concentration in this embodiment may be in the range of 1×10¹⁷ to 1×10¹⁹ dopant atoms/cm³. In one particular embodiment, the second conductivity type dopant concentration within the gate fin portions 124 is greater than 5×10¹⁷ dopant atoms/cm³.

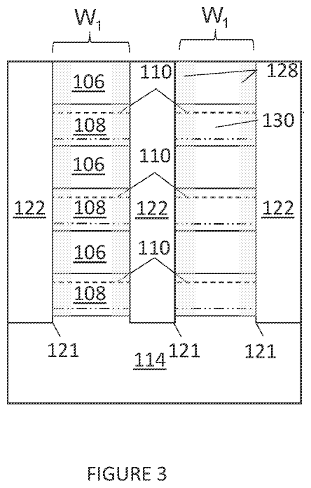

Referring to FIG. 3, another embodiment of the high-electron mobility transistor 100 is shown wherein the gate fin portions 124 are doped with second conductivity type dopant atoms. In this embodiment, the second conductivity type dopant atoms are laterally non-homogeneously distributed across a width of each of the gate fin portions 124. Thus, in contrast to the embodiment of FIG. 2 described above, there may be a considerable difference of second conductivity type dopant concentration at different lateral locations within the gate fin portions 124. In this context, a laterally non-homogeneous distribution refers to an arrangement whereby the minimum difference of dopant concentration along the entire width W₁ of the gate fin portions 124 at one vertical level is more than 10%. This laterally non-homogeneous distribution can be achieved through appropriate selection of the diffusion parameters, e.g., time and temperature and/or the width W₁ of the gate fin portion 124.

In the embodiment of FIG. 3, the gate fin portions 124 comprise first and second high doped regions 128 that directly adjoin sidewalls of two immediately adjacent ones of the gate columns 122 and a low doped region 130 in between the first and second high doped regions 128. The gate fin portions 124 have a lower second conductivity type dopant concentration in the low doped region 130 than in the first and second high doped regions 128. For example, the gate fin portions 124 may have a second conductivity type doping concentration in the range of 1×10¹⁷ to 1×10¹⁹ dopant atoms/cm³ within the first and second high doped regions 128 and may have a second conductivity type doping concentration in the range of 1×10¹⁴ to 1×10 dopant atoms/cm³ within the low doped region 130 and/or a second conductivity type doping concentration that is at least 1000 times lower within the low doped region 130. In this case, the dopant concentration may be substantially uniform in each of the first and second high doped regions 128 and the low doped region 130 such that there is an abrupt transition in dopant concentration between the regions. One way to conceptualize this embodiment is that it reduces the effective width of the gate fin portions 124. That is, the first and second high doped regions 128 serve as extensions of the gate columns 122 and effectively supplant the two-dimensional first charge type gas channel 110, with the low doped region 130 being the region of the gate fin portions 124 that accommodates the load current.

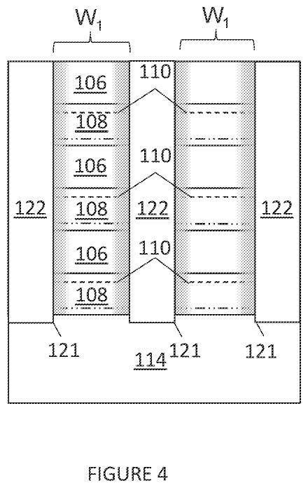

Referring to FIG. 4, another embodiment of the high-electron mobility transistor 100 is shown wherein the gate fin portions 124 are doped with second conductivity type dopant atoms. In this embodiment, the second conductivity type dopant atoms are laterally non-homogeneously distributed across a width of each of the gate fin portions 124. Different to the previous embodiment of FIG. 4, the concentration of the second conductivity type dopant atoms decreases proportionally moving away from the gate columns 122 and towards a center of the gate fin portions 124. For example, the concentration of the second conductivity type dopant atoms may change linearly or exponentially moving away from the gate columns 122. The highest second conductivity type doping concentration in the gate fin portions 124 may be in the range of 1×10¹⁷ to 1×10¹⁹ dopant atoms/cm³ and may occur at the sidewalls of the gate trenches 121. The lowest second conductivity type doping concentration in the gate fin portions 124 may be in the range of 1×10¹⁵ to 1×10¹⁷ dopant atoms/cm³, and/or may be least 100 times lower than the highest second conductivity type doping concentration and may occur at a lateral center of the gate fin portions 124. This laterally non-homogeneous distribution can be achieved through appropriate selection of the diffusion parameters, e.g., time and temperature and/or the width of the gate fin portions 124. One way to conceptualize this dopant distribution is a combination of the embodiments of FIGS. 2 and 3 as described above, wherein the effective width of the gate fin portions 124 is reduced and there is significant charge compensation in the central part of the gate fin portions 124, thus enabling easier depletion control.

The high-electron mobility transistor 100 according to any of the above-described embodiments may be configured as a normally-off device, wherein the width W₁ of the gate fin portions 124 may exceed that which is possible without doping in the gate fin portions 124. For example, the width W₁ of the gate fin portions 124 may be at least 50 nm, at least 60 nm, at least 70 nm, at least 80 nm, etc. Further, the embodiments disclosed herein allow for the width W₁ of the gate fin portions 124 to be significantly greater than these values, while still maintaining a normally-off device configuration. For example, according to an embodiment, the W₁ of the gate fin portions 124 is between 100 nm and 300 nm and the device has a normally-off device configuration. For example, according to an embodiment, the W₁ of the gate fin portions 124 is at least 100 nm, at least 150 nm, at least 200 nm, or more, and the device has a normally-off device configuration. Further, a high-electron mobility transistor 100 having gate fin portions 124 width these width W₁ values may comprise at least three of the two-dimensional first charge type gas channels, at least four of the two-dimensional first charge type gas channels, at least four of the two-dimensional first charge type gas channels, or more.

The high-electron mobility transistor 100 according to any of the above-described embodiments may be configured such that an average concentration of free first charge type carriers within the access region 126 of the high-electron mobility transistor is 5e¹²/cm² per 500 nm vertical thickness. In this context, 500 nm vertical thickness refers to a cross-section of the channel region 104 that extends perpendicular to the upper side 101 of the channel region 104. The average concentration may be observed across an entire area of the access region 126. By maintaining this average concentration of free first charge type carriers at this level within the access region 126, the on-state conduction characteristics of the high-electron mobility transistor 100 remain favorably high. The localized doping techniques for providing the second conductivity type doping mainly within the gate fin regions 124 described herein advantageously allow for a reduction in concentration of free first charge type carriers within the gate fin regions 124 while maintaining this favorable conduction characteristic within access region 126. Stated another way, the localized doping of the device allows for the threshold voltage of the device to be shifted positively without significantly detrimentally impacting conduction in the access region 126. For example, a normally-off device may have the above-disclosed second conductivity type dopant concentration values within the gate fin portions 124, and the width W₁ of the gate fin portions 124 may be 40 nm, 50 nm, 75 nm, 100 nm, 150 nm, 200 nm, 250 nm or more, while maintaining an average concentration of free first charge type carriers within the access region 126 of 5e¹²/cm² per 500 nm vertical thickness.

Although the present disclosure is not so limited, the following numbered examples demonstrate one or more aspects of the disclosure.

Example 1. A high-electron mobility transistor, comprising: a semiconductor body comprising a plurality of type III-nitride semiconductor layers stacked on top of one another, thereby forming a plurality of two-dimensional first charge type gas channels that are vertically spaced apart from one another; source and drain electrodes that are laterally spaced apart from one another and in ohmic contact with each of the two-dimensional first charge type gas channels; a gate structure comprising a plurality of gate columns that extend into the semiconductor body and define gate fin portions of the semiconductor body in between two of the gate columns, wherein the gate structure is configured to control a conductive connection between the source and drain electrodes by controlling a conductive state of each of the two-dimensional first charge type gas channels within the gate fin portions, and wherein the gate fin portions are doped with second conductivity type dopant atoms, thereby locally reducing a concentration of free first charge type carriers within the gate fin portions.

Example 2. The high-electron mobility transistor of example 1, wherein the gate columns comprise second conductivity type semiconductor material that directly interfaces with the type III-nitride semiconductor layers, and wherein the second conductivity type dopant atoms are diffused out from the second conductivity type semiconductor material of the gate columns.

Example 3. The high-electron mobility transistor of example 2, wherein the second conductivity type dopant atoms are substantially laterally homogeneously distributed across a width of each of the gate fin portions.

Example 4. The high-electron mobility transistor of example 3, wherein an average concentration of second conductivity type dopant atoms within the gate fin portions is greater than 5×1017 dopant atoms/cm3.

Example 5. The high-electron mobility transistor of example 2, wherein the second conductivity type dopant atoms are laterally non-homogeneously distributed across a width of the each of the gate fin portions.

Example 6. The high-electron mobility transistor of example 5, wherein the gate fin portions comprise first and second high doped regions that directly adjoin sidewalls of two immediately adjacent ones of the gate columns and a low doped region in between the first and second high doped regions, and wherein the gate fin portions have a lower second conductivity type dopant concentration in the low doped region than in the first and second high doped regions.

Example 7. The high-electron mobility transistor of example 7, wherein the second conductivity type dopant atoms are substantially laterally homogeneously distributed across a width of each of the first and second high doped regions.

Example 8. The high-electron mobility transistor of example 5, wherein a concentration of the second conductivity type dopant atoms decreases proportionally moving away from the gate columns and towards a center of the gate fin portions.

Example 9. The high-electron mobility transistor of example 1, wherein an average concentration of free first charge type carriers within an access region of the high-electron mobility transistor is greater than 5e12/cm2 per 500 nm vertical thickness, the access region being between the gate structure and the drain electrode.

Example 10. The high-electron mobility transistor of example 1, wherein the plurality of type III-nitride semiconductor layers comprises a plurality of layer pairs, wherein each layer pair comprises a barrier layer and a channel layer, wherein each barrier layer is a layer of AlxGa1-xN and each channel layer is a layer of AlyGa1-yN, wherein x>y.

Example 11. The high-electron mobility transistor of example 10, wherein the wherein the gate columns comprise p-type AlGaN.

Example 12. A high-electron mobility transistor, comprising: a semiconductor body comprising a plurality of type III-nitride semiconductor layers stacked on top of one another, thereby forming a plurality of two-dimensional first charge type gas channels that are vertically spaced apart from one another; source and drain electrodes that are laterally spaced apart from one another and in ohmic contact with each of the two-dimensional first charge type gas channels; a gate structure comprising a plurality of gate columns that extend into the semiconductor body and define gate fin portions of the semiconductor body in between two of the gate columns, wherein the gate structure is configured to control a conductive connection between the source and drain electrodes by controlling a conductive state of each of the two-dimensional first charge type gas channels within the gate fin portions, and wherein the high-electron mobility transistor is a normally-off device, and wherein a width of the gate fin portions is at least 80 nm.

Example 13. The high-electron mobility transistor of example 12, wherein the width of the gate fin portions is at least 100 nm.

Example 14. The high-electron mobility transistor of example 12, wherein the width of the gate fin portions is between 50 nm and 300 nm.

Example 15. The high-electron mobility transistor of example 12, wherein the gate columns comprise second conductivity type semiconductor material that directly interfaces with the type III-nitride semiconductor layers.

Example 16. A method of forming a high-electron mobility transistor, the method comprising: providing a semiconductor body comprising a plurality of type III-nitride semiconductor layers stacked on top of one another, thereby forming a plurality of two-dimensional first charge type gas channels that are vertically spaced apart from one another; forming source and drain electrodes that are laterally spaced apart from one another and in ohmic contact with each of the two-dimensional first charge type gas channels; forming a gate structure comprising a plurality of gate columns that extend into the semiconductor body and define gate fin portions of the semiconductor body in between two of the gate columns, the gate structure being configured to control a conductive connection between the source and drain electrodes by controlling a conductive state of the plurality of two-dimensional first charge type gas channels within the gate fin portions, and doping the gate fin portions with second conductivity type dopant atoms, thereby locally reducing a concentration of free first charge type carriers within the gate fin portions.

Example 17. The method of example 16, wherein forming the gate structure comprises: forming a plurality of gate trenches that extend through the plurality of type III-nitride semiconductor layers; and filling each of the gate trenches with second conductivity type semiconductor material.

Example 18. The method of example 15, wherein doping the gate fin portions comprises diffusing the second conductivity type dopant atoms out from the second conductivity type semiconductor material that is within the gate trenches.

Example 19. The method of example 14, wherein the second conductivity type dopant atoms are diffused such that the second conductivity type dopant atoms are substantially laterally homogeneously distributed across a width of each of the two-dimensional first charge type gas channels.

Example 20. The method of example 14, wherein the second conductivity type dopant atoms are diffused such that the second conductivity type dopant atoms are substantially non-homogeneously distributed throughout the gate fin portions.

The device features disclosed herein, for example the doping of the gate fin portions 124, can be incorporated into many different types of multi-channel high-electron mobility transistor devices. These different types of multi-channel high-electron mobility transistor devices can have different numbers of two-dimensional first charge carrier type gas channels 110 and/or two-dimensional second charge type gas channels 112 from what is shown. Examples of multi-channel high-electron mobility transistors are disclosed in U.S. Pat. No. 9,035,355 to Ostermaier, the content of which is incorporated by reference herein in its entirety, U.S. Pat. No. 9,647,104 to Ostermaier, the content of which is incorporated by reference herein in its entirety, U.S. Pat. No. 9,837,520 to Ostermaier, the content of which is incorporated by reference herein in its entirety, and U.S. Pat. No. 11,257,941 to Detzel, the content of which is incorporated by reference herein in its entirety.

In the above description, the heterojunction forming layers of the semiconductor body 102, i.e., the channel layer 108 and barrier layer 106, are disclosed as GaN based semiconductor layers. GaN/AlGaN is used for illustrative purposes only. More generally, any of a variety of combinations of type III-nitride semiconductor materials can be used to provide the device concept described herein. Examples of these materials include, inter alia, gallium arsenide (GaAs), gallium phosphide (GaP), indium phosphide (InP), indium gallium nitride (InGaN) and indium gallium arsenide (InGaAs). In a broad sense, the compound semiconductor transistors described herein can be formed from any binary, ternary or quaternary type III-nitride semiconductor materials where piezoelectric effects are responsible for the device concept.

As used herein, the width W₁ of the gate fin portions 124 refers to the minimum distance between two immediately adjacent ones of the gate columns 122 in the second lateral direction LD2. In the case of a tapered gate fin portion 124, the width W₁ of the gate fin portions 124 is measured at the narrowest part of the gate fin portion 124.

The present specification refers to a “first charge carrier type” and a “second charge carrier type.” In this context, the term “charge carrier type” refers to the polarity of charge carriers. The first charge carrier type may refer to electrons with the second charge carrier type referring to holes, or vice-versa. The “first charge carrier type gas channels” may refer to 2DEG channels and “second charge carrier type gas channels” may refer to 2DHG channels, or vice-versa.

The present specification refers to a “first conductivity type” semiconductor material and a “second conductivity type” semiconductor material. In this context, the term “conductivity type” refers to a net majority dopant type of the semiconductor material. First conductivity type semiconductor material may be n-type material and second conductivity type semiconductor material may be p-type material, or vice-versa.

The term HEMT is also commonly referred to as HFET (heterostructure field effect transistor), MODFET (modulation-doped FET) and MESFET (metal semiconductor field effect transistor). The terms HEMT, HFET, MESFET and MODFET are used interchangeably herein to refer to any III-nitride based compound semiconductor transistor incorporating a junction between two materials with different band gaps (i.e., a heterojunction) as the channel.

The term “electrically connected” intends to describe a low-ohmic electric connection between the elements electrically connected together, e.g., a connection via a metal and/or highly doped semiconductor.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A high-electron mobility transistor, comprising:
a semiconductor body comprising a plurality of type III-nitride semiconductor layers stacked on top of one another, thereby forming a plurality of two-dimensional first charge type gas channels that are vertically spaced apart from one another;
source and drain electrodes that are laterally spaced apart from one another and in ohmic contact with each of the two-dimensional first charge type gas channels;
a gate structure comprising a plurality of gate columns that extend into the semiconductor body and define gate fin portions of the semiconductor body in between two of the gate columns,
wherein the gate structure is configured to control a conductive connection between the source and drain electrodes by controlling a conductive state of each of the two-dimensional first charge type gas channels within the gate fin portions, and
wherein the gate fin portions are doped with second conductivity type dopant atoms, thereby locally reducing a concentration of free first charge type carriers within the gate fin portions.

2. The high-electron mobility transistor of claim 1, wherein the gate columns comprise second conductivity type semiconductor material that directly interfaces with the type III-nitride semiconductor layers, and wherein the second conductivity type dopant atoms are diffused out from the second conductivity type semiconductor material of the gate columns.

3. The high-electron mobility transistor of claim 2, wherein the second conductivity type dopant atoms are substantially laterally homogeneously distributed across a width of each of the gate fin portions.

4. The high-electron mobility transistor of claim 3, wherein an average concentration of second conductivity type dopant atoms within the gate fin portions is greater than 5×10¹⁷ dopant atoms/cm³.

5. The high-electron mobility transistor of claim 2, wherein the second conductivity type dopant atoms are laterally non-homogeneously distributed across a width of the each of the gate fin portions.

6. The high-electron mobility transistor of claim 5, wherein the gate fin portions comprise first and second high doped regions that directly adjoin sidewalls of two immediately adjacent ones of the gate columns and a low doped region in between the first and second high doped regions, and wherein the gate fin portions have a lower second conductivity type dopant concentration in the low doped region than in the first and second high doped regions.

7. The high-electron mobility transistor of claim 6, wherein the second conductivity type dopant atoms are substantially laterally homogeneously distributed across a width of each of the first and second high doped regions.

8. The high-electron mobility transistor of claim 5, wherein a concentration of the second conductivity type dopant atoms decreases proportionally moving away from the gate columns and towards a center of the gate fin portions.

9. The high-electron mobility transistor of claim 1, wherein an average concentration of free first charge type carriers within an access region of the high-electron mobility transistor is greater than 5e¹²/cm² per 500 nm vertical thickness, the access region being between the gate structure and the drain electrode.

10. The high-electron mobility transistor of claim 1, wherein the plurality of type III-nitride semiconductor layers comprises a plurality of layer pairs, wherein each layer pair comprises a barrier layer and a channel layer, wherein each barrier layer is a layer of AlₓGa1₋ₓN and each channel layer is a layer of AlyGa1-yN, wherein x>y.

11. The high-electron mobility transistor of claim 10, wherein the wherein the gate columns comprise p-type AlGaN.

12. A high-electron mobility transistor, comprising:
a semiconductor body comprising a plurality of type III-nitride semiconductor layers stacked on top of one another, thereby forming a plurality of two-dimensional first charge type gas channels that are vertically spaced apart from one another;
source and drain electrodes that are laterally spaced apart from one another and in ohmic contact with each of the two-dimensional first charge type gas channels;
a gate structure comprising a plurality of gate columns that extend into the semiconductor body and define gate fin portions of the semiconductor body in between two of the gate columns,
wherein the gate structure is configured to control a conductive connection between the source and drain electrodes by controlling a conductive state of each of the two-dimensional first charge type gas channels within the gate fin portions, and
wherein the high-electron mobility transistor is a normally-off device, and
wherein a width of the gate fin portions is at least 80 nm.

13. The high-electron mobility transistor of claim 12, wherein the width of the gate fin portions is at least 100 nm.

14. The high-electron mobility transistor of claim 12, wherein the width of the gate fin portions is between 80 nm and 300 nm.

15. The high-electron mobility transistor of claim 12, wherein the gate columns comprise second conductivity type semiconductor material that directly interfaces with the type III-nitride semiconductor layers.

16. A method of forming a high-electron mobility transistor, the method comprising:
providing a semiconductor body comprising a plurality of type III-nitride semiconductor layers stacked on top of one another, thereby forming a plurality of two-dimensional first charge type gas channels that are vertically spaced apart from one another;
forming source and drain electrodes that are laterally spaced apart from one another and in ohmic contact with each of the two-dimensional first charge type gas channels;
forming a gate structure comprising a plurality of gate columns that extend into the semiconductor body and define gate fin portions of the semiconductor body in between two of the gate columns, the gate structure being configured to control a conductive connection between the source and drain electrodes by controlling a conductive state of the plurality of two-dimensional first charge type gas channels within the gate fin portions, and
doping the gate fin portions with second conductivity type dopant atoms, thereby locally reducing a concentration of free first charge type carriers within the gate fin portions.

17. The method of claim 16, wherein forming the gate structure comprises:
forming a plurality of gate trenches that extend through the plurality of type III-nitride semiconductor layers; and
filling each of the gate trenches with second conductivity type semiconductor material.

18. The method of claim 17, wherein doping the gate fin portions comprises diffusing the second conductivity type dopant atoms out from the second conductivity type semiconductor material that is within the gate trenches.

19. The method of claim 18, wherein the second conductivity type dopant atoms are diffused such that the second conductivity type dopant atoms are substantially laterally homogeneously distributed across a width of each of the two-dimensional first charge type gas channels.

20. The method of claim 18, wherein the second conductivity type dopant atoms are diffused such that the second conductivity type dopant atoms are substantially non-homogeneously distributed throughout the gate fin portions.
